(19) United States
(12) Patent Application Publication
(10) Pub. No.: US 2011/0168976 A1
(43) Pub. Date: Jul. 14, 2011

(54) MICRO- AND NANO-STRUCTURED LED AND OLED DEVICES

(75) Inventor: Samuel S. Mao, Castro Valley, CA (US)

(73) Assignee: THE REGENTS OF THE UNIVERSITY OF CALIFORNIA, Oakland, CA (US)

(21) Appl. No.: 13/002,482

(22) PCT Filed: Jul. 23, 2009
(86) PCT No.: PCT/US2009/051574

§ 371 Date: Mar. 25, 2011

Related U.S. Application Data
(60) Provisional application No. 61/083,350, filed on Jul. 24, 2008.

(51) Int. Cl. H01L 33/06; B82Y 99/00; B82Y 40/00

(52) U.S. Cl. 257/13; 438/47; 257/E33.008; 977/734; 977/932; 977/842

(57) ABSTRACT

Structured LED devices and component structures with improved efficiency and reduced defects are enabled by the use of micro- or nano-structured features that reduce lattice strain and improve p-doping in inorganic LEDs, and facilitate carrier injection and recombination of OLEDs. The nanostructures can also confine current flow and provide internal light guiding to enhance efficiency and thereby improve device performance.

### CROSS-REFERENCE TO RELATED APPLICATIONS

This application claims priority to U.S. Provisional Patent Application No. 61/083,350, titled MICRO- AND NANO-STRUCTURED LED AND OLED DEVICES, filed Jul. 24, 2008, the disclosure of which is incorporated herein by reference in its entirety and for all purposes.

### STATEMENT OF GOVERNMENTAL SUPPORT

The invention described and claimed herein was made at least in part utilizing funds supplied by the U.S. Department of Energy under Contract No. DE-AC02-05CH11231. The Government has certain rights in this invention.

### BACKGROUND OF THE INVENTION

A light-emitting diode (LED) is a semiconductor diode that emits light when electrically biased in the forward direction of the p-n junction. The color of the emitted light depends on the composition and condition of the semiconducting material used, and can be infrared, visible, or ultraviolet. As in other diodes, an LED is a semiconducting structure consisting of p- and n-type semiconductor materials, which can be achieved by doping the materials with impurities, to create a p-n junction. Current flows from the anode to the cathode, but not in the reverse direction. Charge carriers—electrons and holes—flow into the junction from electrodes with different voltages. When an electron meets a hole, it falls into a lower energy level, and releases energy in the form of a photon.

The wavelength of the light emitted, and therefore its color, depends on the band gap energy of the materials forming the p-n junction. In silicon or germanium diodes, the most common commercially, the electrons and holes recombine by a non-radiative transition which produces no optical emission because these are indirect band gap materials. Semiconductor materials used for LEDs have a direct band gap with energies corresponding to near-infrared, visible or near-ultraviolet light.

Conventional LEDs typically have a multilayer film structure. Most conventional LEDs are composed of inorganic materials, typically a p-doped semiconductor material grown or deposited on an n-doped substrate, or vice versa. GaN/InGaN is a common combination in short wavelength inorganic LEDs.

LEDs can also be made using organic light emitting layer materials. Known as Organic Light Emitting Diodes (OLEDs), these devices include an emissive electroluminescent layer composed of an organic polymer or small molecule film. Poly(3,4-ethylenedioxythiophene) (PEDOT) and tris(8-hydroxyquinolinato)aluminum (Al(C₉H₆NO)₃), (Alq³), are p-type and n-type, respectively, organic emissive electroluminescent materials commonly used in OLEDs.

Early LEDs emitted light with a relatively long wavelength in the visible spectrum, so having red, orange and yellow colors. More recently, the use of shorter wavelength emitters has enabled blue light LEDs and made possible the development of white light LEDs (by combining long and short wavelength emitters), useful for illumination.

Developers of short wavelength LED devices have faced challenges of high defect concentration and difficulty p-type doping. Also, the efficiency of LEDs and OLEDs remains limited.

### SUMMARY OF THE INVENTION

The present invention provides structured LED and OLED devices and component structures with improved efficiency and reduced defects. The improved performance of these devices is enabled by the use of micro- or nano-structured features that reduce lattice strain and improve p-doping in inorganic LEDs, and facilitate carrier injection and recombination of OLEDs. The structures can also confine current flow and provide internal light guiding to enhance efficiency and thereby improve device performance.

Also provided are fabrication techniques for structured LED devices.

These and other aspects and applications of the structured LED and OLED devices of the present invention are described in more detail in the description that follows.

### BRIEF DESCRIPTION OF THE DRAWINGS

The foregoing aspects and others will be readily appreciated by the skilled artisan from the following description of illustrative embodiments when read in conjunction with the accompanying drawings.

FIG. 1A shows a schematic illustration of two examples of nanoscale crystalline heterostructures grown by nanoscale heteroepitaxy, one with and one without a patterned substrate, according to embodiments of the invention.

FIG. 1B shows schematic views of two types of inorganic LED device designs incorporating nanoscale crystalline heterostructures grown by nanoscale heteroepitaxy, according to embodiments of the invention.

FIGS. 2A-E depict operations in a method of making an inorganic LED device design incorporating nanoscale crystalline heterostructures grown by nanoscale heteroepitaxy, according to an embodiment of the invention.

FIGS. 3A-C depict operations in another method of making an inorganic LED device design incorporating nanoscale crystalline heterostructures grown by nanoscale heteroepitaxy, according to an embodiment of the invention.

FIGS. 4A-C depict operations in another method of making an inorganic LED device design incorporating nanoscale crystalline heterostructures grown by nanoscale heteroepitaxy, according to an embodiment of the invention.

FIG. 5A illustrates a general structure for an OLED in accordance with the invention.

FIG. 5B illustrates a specific example of an OLED in accordance with an embodiment of the present invention.

FIG. 5C is a schematic top view representing an example of OLED emissive material nanostructures in accordance with the invention.

FIG. 5D is an electron micrograph of a specific example of OLED emissive material nanostructures in accordance with the invention.

FIG. 5E depicts a plot of voltage vs. current efficiency for a conventional, multilayered (unstructured) OLED and a nanostructured (structured) OLED in accordance with the invention.

FIGS. 6A-G illustrate aspects of the fabrication of OLED devices in accordance with the present invention.

FIG. 7 illustrates schematically a bi-layer anode with porous metal oxide deposited on a glass substrate, and the basic OLED device structure after the incorporation of an ultra-low density porous metal oxide layer on the top of ITO.

FIG. 8 is a plot showing current efficiency of four OLED devices having the same device structure but different thickness of a porous TiO₂ layer between ITO and the organics.

FIG. 9 illustrates schematically a bi-layer anode comprising ITO and a conductive polymer deposited on a glass substrate, and the basic OLED device structure after the incorporation of imprinted nanostructures.

FIG. 10 illustrates schematically a bi-layer anode deposited on a glass substrate, the basic device structure after incorporation of polymer-demixing induced nanostructures, and a schematic of a flat polymer blend transformed to structured topography.

FIG. 11 provides a schematic illustration of a silica microstructure fabricated with a spin-on glass imprinting (SOGI) process on top of an ITO anode on a glass substrate, and the basic OLED device structure after deposition of multiple layers of organics to form a silica-organic intercalated OLED structure.

FIG. 12 provides a schematic illustration of the mechanism of improved light extraction from the organic emission layer after incorporation of a low refractive index microstructure.

FIGS. 13A-C illustrate the fabrication of a hybrid organic/inorganic LED structure in accordance with the present invention.

### DETAILED DESCRIPTION OF SPECIFIC EMBODIMENTS

Reference will now be made in detail to specific embodiments of the invention. Examples of the specific embodiments are illustrated in the accompanying drawings. While the invention will be described in conjunction with these specific embodiments, it will be understood that it is not intended to limit the invention to such specific embodiments. On the contrary, it is intended to cover alternatives, modifications, and equivalents as may be included within the spirit and scope of the appended claims. In the following description, numerous specific details are set forth in order to provide a thorough understanding of the present invention. The present invention may be practiced without some or all of these specific details. In other instances, well known process operations have not been described in detail so as to not unnecessarily obscure the present invention.

### INTRODUCTION

The present invention uses a nanostructured approach as an alternative to conventional unstructured multi-layer films for inorganic and organic LED fabrication. The approach provides micro- or nano-structured LED devices and component structures with improved efficiency and reduced defects. The improved performance of these devices is enabled by the use of micro- or nano-structured features that reduce lattice strain and improve p-doping in inorganic LEDs, and facilitate carrier injection and recombination of OLEDs. The micro- or nano-structures can also confine current flow and provide internal light guiding to enhance efficiency and thereby improve device performance.

Nano-heteroepitaxy is a technique for dramatically extending the thickness of defect-free crystal growth in highly mismatched heterostructures. It exploits the three-dimensional stress relief mechanism at the nanometer (i.e., 5 to <1000 nm, particularly 50-500 nm, e.g., 100 nm feature size) and applies it to reduce the strain energy in lattice-mismatched heterojunctions. The same technique is also applicable in the micrometer scale (i.e., 1 to 100 μm, e.g., 5-50 μm feature size) and the description of the nano-heteroepitaxy technique below, and other description relating to nanoscale structures, should be understood to be applicable to the micro scale as well.

Inorganic LEDs

Inorganic LED device design in accordance with the present invention achieves efficient light emission from wide band-gap, low defect concentration, nanostructured materials, such as GaN and ZnO. The techniques and structures of the invention can achieve low defect concentration and p-type doping of nanoscale crystalline quality materials by use of crystalline nanostructures, such as nanorods, instead of conventional films covering the substrate.

When an epilayer grows on a lattice mismatched substrate the strain energy increases linearly until at some point mismatched dislocations are created to reduce strain. Due to the nonexistence of lattice-matching substrates it is extremely difficult to reduce this type of defect concentration in wide band-gap semiconductor films.

The present invention uses nanoscale heteroepitaxy, a fundamentally different epitaxial growth approach that uses the growth of crystalline nanostructures, such as nanorods/columns, to avoid defects caused by stress relief via mismatched dislocations. In this nanoscale heteroepitaxy growth mode, strain falls exponentially with distance from the growth interface.

It is possible to make nanostructures, such as nanorods, with high crystalline quality by nanoscale heteroepitaxy, which is a technique for dramatically extending the thickness of defect-free crystal growth in highly mismatched heterostructures. It exploits the three-dimensional stress relief mechanism at the nanometer scale and applies it to reduce the strain energy in lattice-mismatched hetero-junctions. The spacing between the nanostructures on the substrate reduces the strain associated with the lattice mismatch between the substrate semiconductor (e.g., silicon and GaAs) and the emissive electroluminescent semiconductor (e.g., GaN). Reduction of strain at the interface avoids misfit dislocations and leads to a lower defect density.

Nanoscale heteroepitaxy can be achieved with or without patterning the substrate on which the nano-crystalline semiconductors grow. For example, if the substrate is patterned, nanoscale heteroepitaxy combines three-dimensional stress relief with strain partitioning on the top layers of the substrate. As heteroepitaxy proceeds, the nanoscale epilayer and the nanoscale substrate seed island both undergo three-dimensional strain. This partitioning of strain between the epilayer and substrate is manifested as exponentially decaying strain on both sides of the hetero-interface. Nanoscale heteroepitaxy without patterning can be achieved by: (1) masking the substrate in the non-growth area; (2) pre-deposition of self-assembled metallic catalysts (e.g., Au) in the growth area.

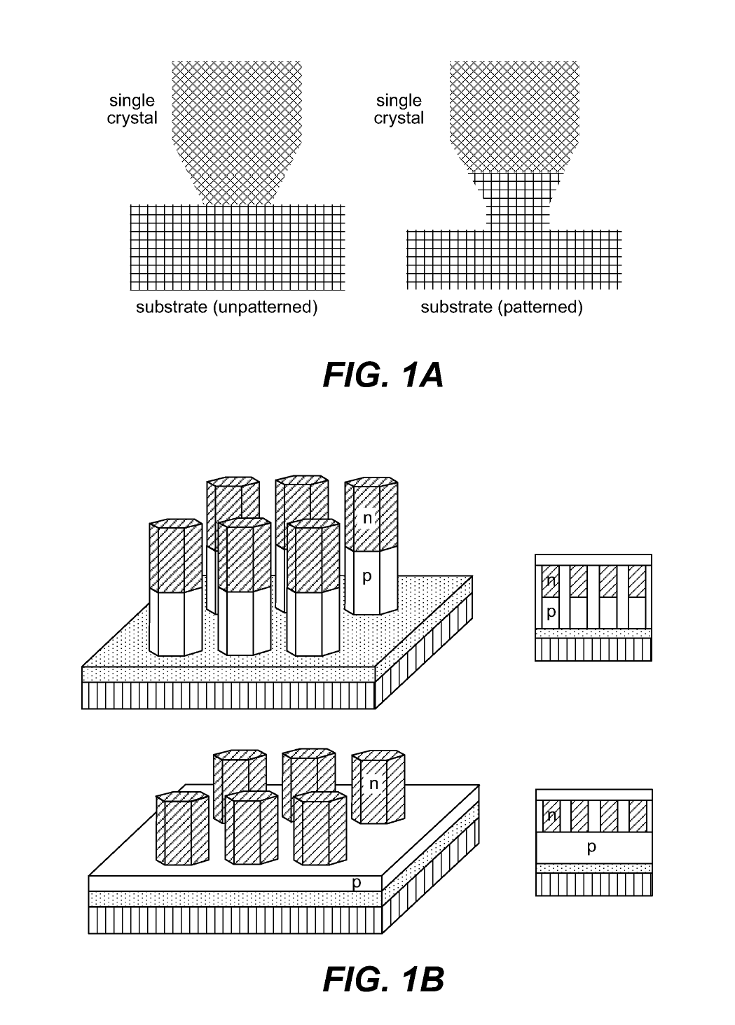

FIG. 1A shows a schematic illustration of two examples of nanoscale crystalline heterostructures grown by nanoscale heteroepitaxy, one with and one without a patterned substrate. LED devices in accordance with the present invention incorporating such nanostructures have demonstrated about 100 times the photoluminescence intensity from the nanostructured GaN diode relative to conventional planar-growth LED devices.

Techniques for n-doping high crystalline quality wide band-gap semiconductor materials, such as GaN, are well know and readily adaptable by those skilled in the art. In order to achieve p-type doping in high crystalline quality wide band-gap semiconductor nanostructures (such as nanorods) for LED applications, an ultrafast laser based doping process is used. Because of the ultrashort laser pulse duration, many new phases of the material can be achieved, including dopant inclusion. For instance, the ultrafast laser pulse produces a high temperature vapor of precursor material for nanorod growth. The precursor material comprises a mix of p-type dopant and the material for the LED. Deposition of the precursor vapor on a substrate results in rapid cooling of the precursor, with solidification taking place at a rate of temperature change not achievable by conventional solution chemistry or evaporation approaches.

The invention provides three basic types of inorganic LED device designs incorporating nanoscale crystalline heterostructures grown by nanoscale heteroepitaxy:

(1) Type 1: p-n Type LED Device with p-Type Nanostructure and n-Type Nanostructure:

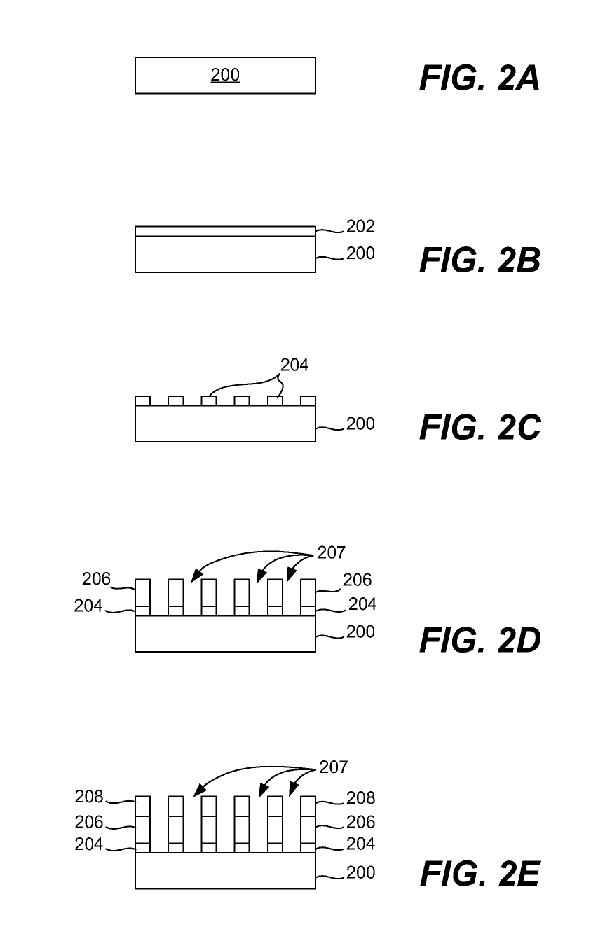

Referring to FIGS. 2A-E, instead of growth of a GaN layer on a Si (or other bulk semiconductor) substrate by conventional techniques, a thin (e.g., about 10-50 nm, for example 20 nm) seed layer of GaN 202 (or other high crystalline quality wide band-gap semiconductor material) is grown on the bulk substrate 200 (FIGS. 2A-B). The seed layer 202 may or may not be doped. The seed layer 202 is then patterned into nm scale islands 204 (e.g., about 100-5000 nm², for example 20×20 nm) using standard lithographic techniques (FIG. 2C). Thereafter, growth of the GaN is continued from the patterned seed layer using an appropriate doped precursor. This results in the growth single crystal doped (e.g., p-doped) GaN columns 206 from the nm scale seed layer islands 204 (FIG. 2D). The gaps 207 between the columns 206 allow for the release of the lattice mismatch strain. Alternatively, nanoscale heteroepitaxy without patterning may be conducted by masking the substrate in the non-growth areas during nanorod growth, according to well-developed semiconductor processing procedures readily adapted to this application by a person skilled in the art given the disclosure provided herein.

In order to obtain the p-n junction 209 required for a LED, crystal growth of the nanorod columns is continued with an alternately doped precursor (e.g., if starting with p; then shift to n) such that, a n-GaN region 208 is grown on top of the n-GaN region, in this example (FIG. 2E).

(2) Type 2: p-n Type LED Device with p-Type Film Structure and n-Type Nanostructure:

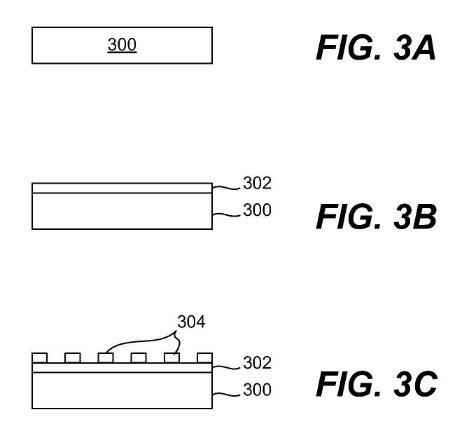

According to another embodiment of the invention, illustrated in FIGS. 3A-C, a bulk semiconductor (generally Si) substrate 300 is provided (FIG. 3A). A doped (e.g., p-doped) Si layer 302 is then formed on top of substrate 300 (FIG. 3B). The p-doped Si Layer may be deposited (e.g., polysilicon) or grown as single crystal Si on the substrate 300. Then, single crystal n-GaN nanorods 304 are grown on the p-doped Si layer by nanoscale heteroepitaxy as described above, with or without patterning, to form the required p-n junction for an LED at the interface of the p-doped Si and n-GaN nanorods (FIG. 3C).

Schematic views of these first two types of inorganic LED device designs incorporating nanoscale crystalline heterostructures grown by nanoscale heteroepitaxy are depicted in FIG. 1B.

(3) Type 3: p-n Type LED Device with n-Type Nanostructure and p-Type Fill

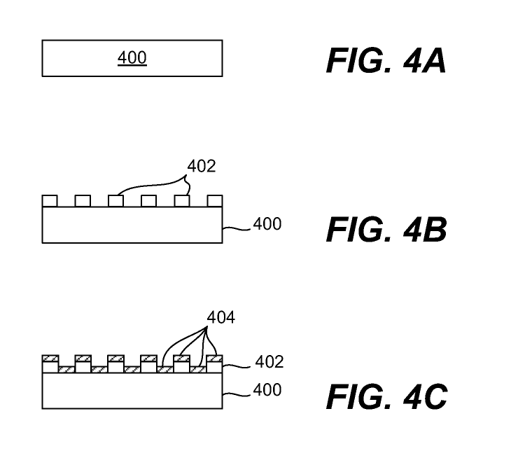

According to still another embodiment of the invention, illustrated in FIGS. 4A-C, a bulk semiconductor (generally Si) substrate 400 is provided (FIG. 4A). Single crystal n-GaN nanorods 402 are grown on the bulk Si 400 by nanoscale heteroepitaxy as described above, with or without patterning (FIG. 4B). Then, p-doped GaN 404 is deposited over the n-GaN nanorods to form the required p-n junction for the LED on top of and/or in between the individual nanostructures 402 (FIG. 4C). The p-GaN deposited on the top of the n-GaN nanostructures (nanorods) can be optionally removed by chemical mechanical polishing (CMP) or ion beam etching, but this is not necessary. If the p-GaN deposited on the top of the n-GaN nanostructures is removed, the n-p junction is on the sidewall of the gap between the individual nanostructures 402. This approach is advantageous from an implementation standpoint since it relies upon well-established semiconductor processing techniques for producing robust structures that are readily adaptable for the purposes of the present invention given the disclosure provided herein.

Once the p-n junction is formed by any of the techniques described above, a metal electrode layer is applied to the top of the LED structure and the electrodes are connected to a voltage source to complete the LED device.

In each of these inorganic LED embodiments of the invention described above, the emissive material nanostructures confine current flow and provide internal light guiding which are believed to provide to improved device performance.

Organic LEDs

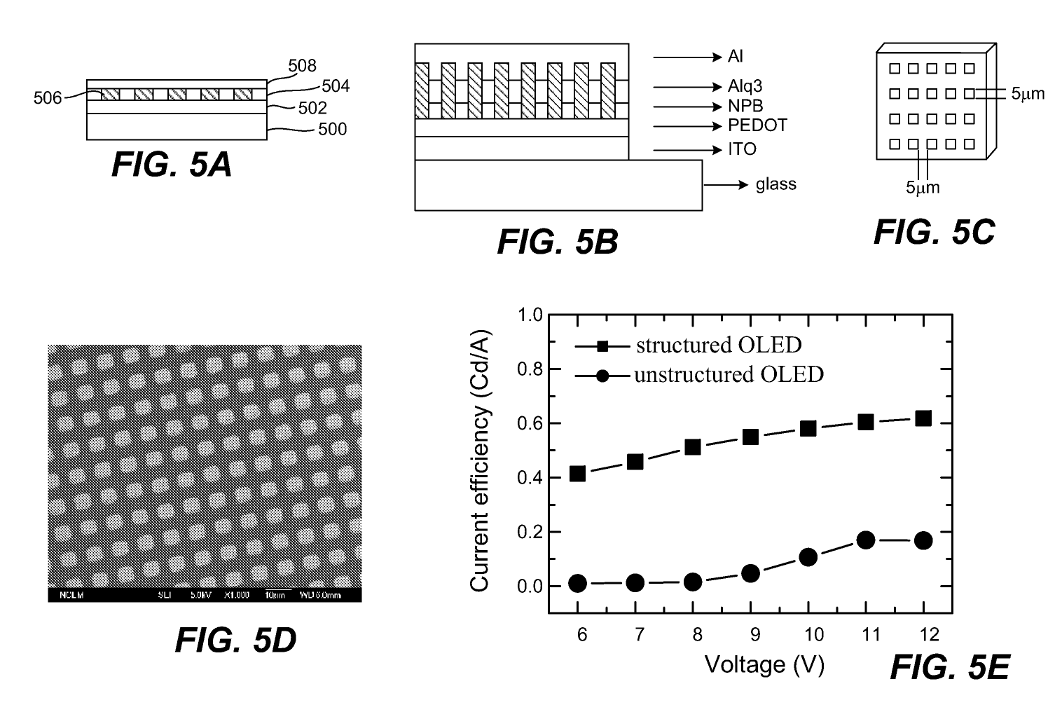

The present invention is also applicable to organic LEDs (OLEDs). The OLED structure of the invention replaces the conventional multilayer structure (substrate-anode-conductive layer-emissive layer-cathode) of an OLED with a design that incorporates micro- or nano-structures. A structure for an OLED in accordance with the invention is shown in cross-section in FIG. 5A. The structure includes an anode layer 502 on a suitable bulk substrate, such as glass, plastic or foil. The anode layer may be transparent to visible light (light can also emit from the cathode) and must have a high work function which promotes injection of holes into the adjacent emissive material 504. A good example is indium tin oxide (ITO). Rather than being in the form of a layer, however, the emissive material 504 is a nanostructure, e.g., a nanorod. A suitable organic emissive material is tris(8-hydroxyquinolinato)aluminum (Al(C₉H₆NO)₃) (Alq³). The emissive material nanostructures 504 are separated by an inactive material 506, such as a non-conducting polymer or SOG. An optional conductive layer (not shown in FIG. 5A) can be provided between the anode and emissive material nanostructures 504, but is not essential to the invention. The structure is completed by a cathode 508 on top of the emissive material nanostructures 504. Metals such as Al, Ca, Mg, Be and their alloys are often used for the cathode as they have low work functions which promote injection of electrons into the emissive material.

A specific example of an OLED in accordance with the present invention is shown in FIG. 5B. The structure includes a layer of indium tin oxide (ITO) semiconductor as the anode on a bulk glass substrate. In this example, a conductive layer of poly(3,4-ethylenedioxythiophene) (PEDOT) and N,N′-diphenyl-N,N′-bis(1-naphthyl)(1,1′-biphenyl)-4,4′diamine (NPB) can be provided between the anode and emissive material nanostructures 504 to enhance hole injection into the emissive material. Emissive material, in this case Alq³, nanostructures are on the conductive polymer and separated by inactive material in the gaps between individual nanostructures. In this case, the inactive material is SiO₂. In other embodiments, as an alternative to SiO₂, any polymer that (1) is non-conductive, (2) has refractive index smaller than the organic materials (therefore forming a total internal reflection cavity) may be used. The structure is completed by an Al cathode on top of the Alq³ emissive material nanostructures.

FIG. 5C is a schematic top view representing an example of emissive material nanostructures in accordance with the invention. The nanostructures are 5×5 um towers. An actual example is shown in an electron micrograph in FIG. 5D. Such OLED nanostructures facilitate carrier injection into the organic material and reduce exciton diffusion out of the cavity, thus improving the efficiency.

FIG. 5E depicts a plot of voltage vs. current efficiency for a conventional, multilayered (unstructured) OLED and a nanostructured (structured) OLED in accordance with the invention. Current efficiency in this context is the amount of voltage is converted to light by the LED. As can be seen from the plot the OLED device of the invention have much higher efficiency that the convention OLED device. In addition, it can be seen that the inventive device has a greatly reduced threshold for light emission; while outside the range of the plot, the threshold value is about 3V.

As with the inorganic LED embodiments of the invention described above, the emissive material micro- or nano-structures in these OLEDs confine current flow and provide internal light guiding which are believed to contribute to the improved device performance.

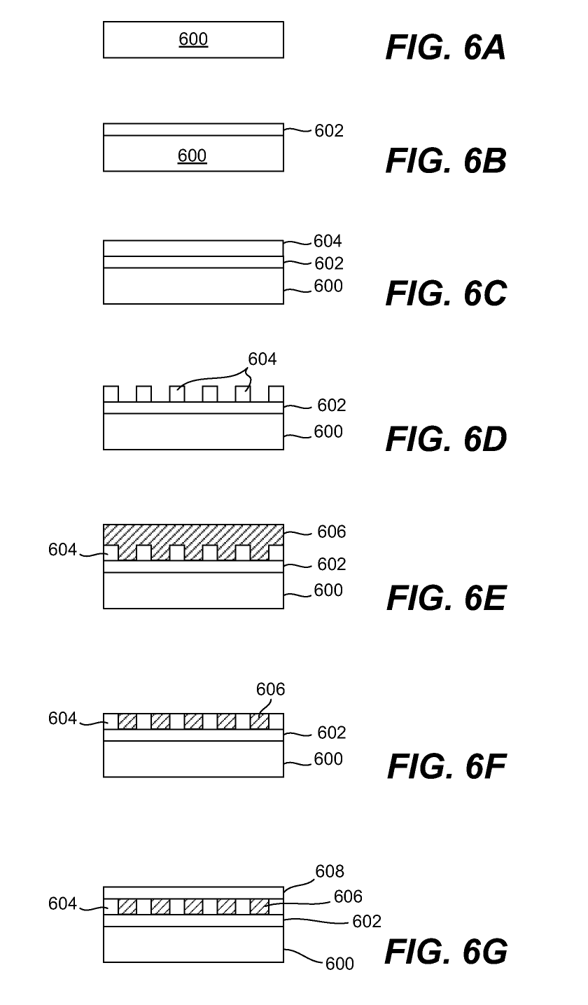

Aspects of the fabrication of OLED devices in accordance with the present invention are illustrated in FIGS. 6A-G. OLEDs in accordance with this embodiment of this aspect of the present invention are formed lithographically according to principles and deposit, pattern and etch techniques well developed in the semiconductor processing field that are readily adaptable to the present invention given the description provided herein.

Referring to FIG. 6A a suitable bulk substrate 600, such as glass, plastic or foil is provided. An anode layer 602 is formed on the substrate 600, such as by sputter deposition (FIG. 6B). The anode layer should be transparent to visible light and have a high work function which promotes injection of holes into the adjacent emissive material. A good example is indium tin oxide (ITO). A suitable emissive material 604 is then formed on the anode, such as by spin on or evaporative deposition (FIG. 6C). A layer of a suitable emissive material is tris(8-hydroxyquinolinato)aluminum (Al(C₉H₆NO)₃) (Alq³). The emissive material layer in patterned and etched into nanostructures (FIG. 6D). An inactive (insulating) material, such as SOG is then deposited over the patterned surface, for example by spin on or CVD (FIG. 6E). The inactive material in then removed back to the level of the emissive material nanostructures (FIG. 6F), for example by ion beam milling. The structure is completed by a depositing a cathode 608 on top of the emissive material nanostructures 604, for example by evaporation.

In an alternative fabrication method, the inactive material 606 may be first deposited on the anode 602, patterned and etched. And then the emissive material 604 may be deposited on the patterned inactive material and etched back in order to form the emissive material nanostructures.

Porous Oxide Interlayer

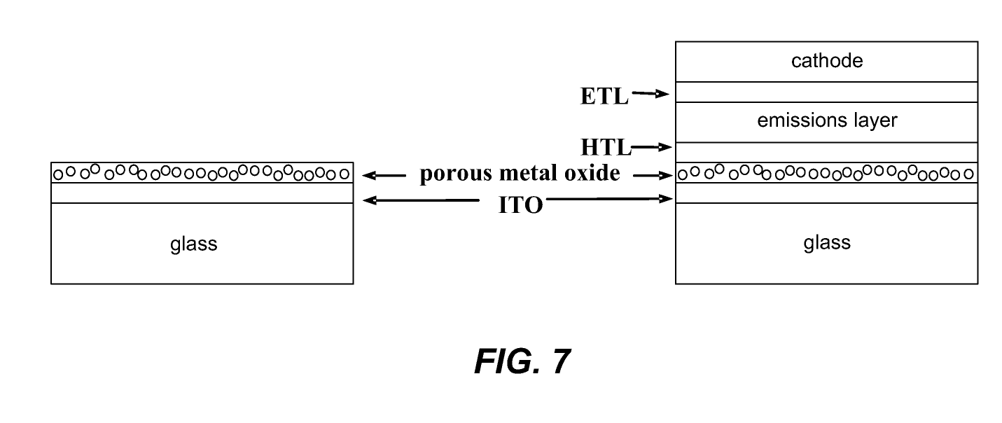

In other embodiments of this aspect of the invention, OLEDs may be fabricated using ultra-low density (e.g., as low as 0.1 g/cm³), highly porous (e.g., as high as 98%) metal oxides, such as TiO₂, MoO₃, WO₃, V₂O₅, etc., deposited between the ITO anode and the organic layer. Suitable materials can be formed using a sol gel approach. Metal oxide aerogels are a suitable material. In a particular embodiment, TiO₂ having a density of about 0.1 g/cm³ and a porosity of about 98% is used. These materials provide a low refractive index porous anode layer that improves the device efficiency by improving light out-coupling, as well as facilitating improved electrical efficiency. FIG. 7 provides a schematic illustration of a bi-layer anode with porous metal oxide deposited on a glass substrate (left), and the basic device structure after the incorporation of an ultra-low density porous metal oxide layer on the top of ITO (right).

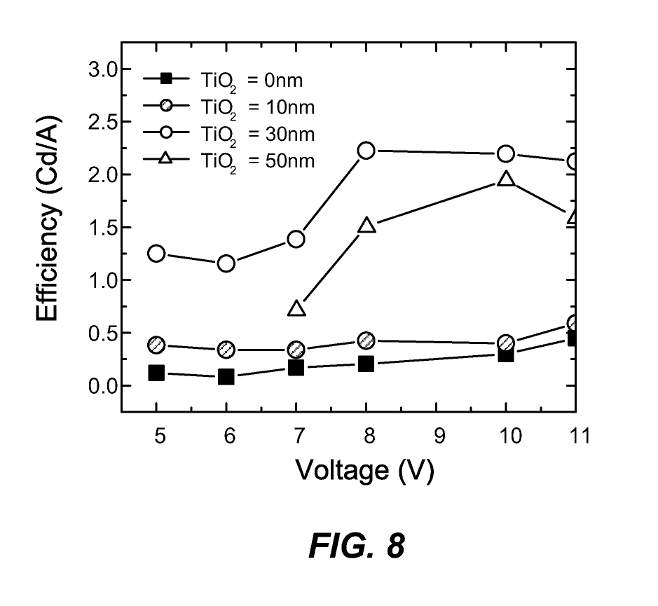

Device testing indicates that the current efficiency increases with the inclusion of the porous oxide layer, which has a low effective refractive index due to the high porosity, together with a deep valence band to block holes for the hole-dominant device. However, the efficiency reduces when the thickness of the layer becomes too thick due to insufficient hole injection. FIG. 8 shows current efficiency measurements of four devices with different thickness of porous TiO₂ layer between ITO and organics. All the devices in this experiment had the same layered structure, except with different porous-TiO₂ thickness: ITO/TiO₂/PEDOT:PSS/NPB/Alq₃/LiF/Al.

Non-Vacuum OLED Fabrication Processes

According to other embodiments of this aspect of the invention, fabrication processes without the need of vacuum are also provided. Such process implementations can enhance scalability and lower manufacturing costs for OLEDs.

Imprinting and Soft Lithography for Structured Hole Injection Layer

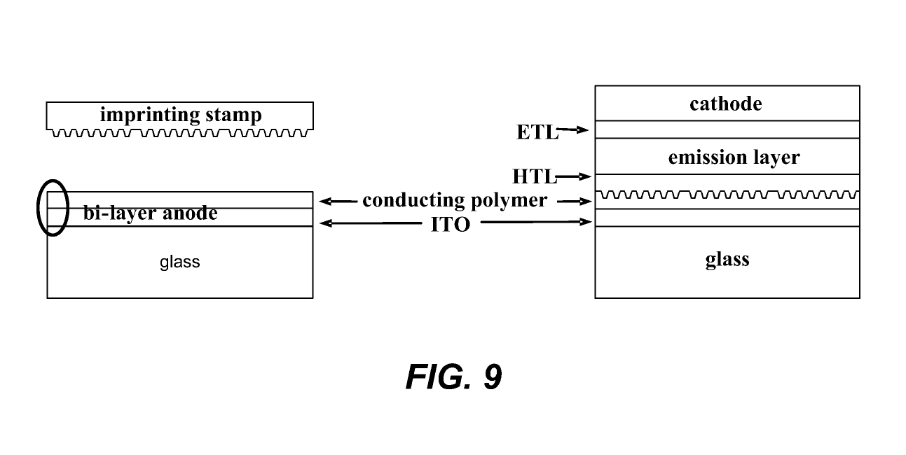

Scalable imprinting and soft lithography-defined periodic and quasi-periodic structures at the anode-organic side of OLEDs can improve hole injection. For imprinting, in the most cost-effective form, a pre-fabricated solid mold (stamp) creates a designed relief structure in a soft organic conducting polymer layer of the device. The dimension of the imprinting structures can be realized as small as on the order of 10 nm. In one example, this aspect of the invention may be implemented using large-scale nano-imprinting technology developed by Hewlett-Packard Corporation, such as is described in Lee, Heon and Jung, Gun-Young, Full Wafer Scale Near Zero Residual Nano-Imprinting Lithography Using UV Curable Monomer Solution, Microelectronic Engineering, Vol. 77, 1, January 2005, 42-47, the imprinting technique of which is incorporated by reference herein. Scalable imprinting can be used to create designed nanostructures at the conducting organic hole injection layer coated on ITO glasses. FIG. 9 illustrates schematically a bi-layer anode comprising ITO (other suitable OLED anode materials may also be used) and a conductive polymer, such as PEDOT, deposited on a glass substrate (left), and the basic OLED device structure after the incorporation of imprinted nanostructures (right). Between the imprinted conducting polymer layer of the anode and the cathode are a hole transport layer (HTL) composed of a material such as NPB, an emission layer composed of a material such as poly(p-phenylene vinylene), and an electron transport layer (ETL) composed of a material such as Alq³. An example of an imprinting stamp is also schematically illustrated (left).

For soft lithography, polymer demixing can be applied for creating a nanostructured anode-organic interface to pattern the conducting organic hole injection layer coated on ITO glasses. In a suitable process, blends of the conducting polymer and a sacrificial polymer (e.g., polystyrene) are dissolved in suitable solvent, such as chloroform, followed by polystyrene removal by a selective solvent. Such a surface-directed polymer demixing process enables the formation of topographically quasi-periodic nanostructures on the conducting polymer surface with dimensions of a few nanometers.

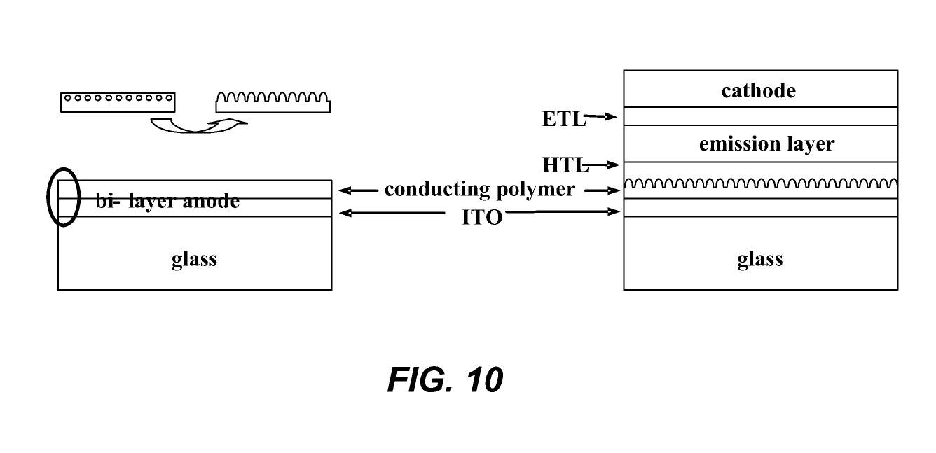

FIG. 10 illustrates schematically a bi-layer anode deposited on a glass substrate (left), and the basic OLED device structure after incorporation of polymer-demixing induced nanostructures (right). A schematic of a flat polymer blend transformed to structured topography is also shown (left).

Spin-on Glass Imprinting (SOGI) for Structured Emission Layer

In addition to structuring the hole injection layer at the anode side of OLEDs to increase device electrical efficiency through improved charge injection, patterning the organic light emission and transport layers can also help improve device performance. The invention also provides a scalable and low cost fabrication technology without the use of photolithography for creating structured emissive layers in OLEDs.

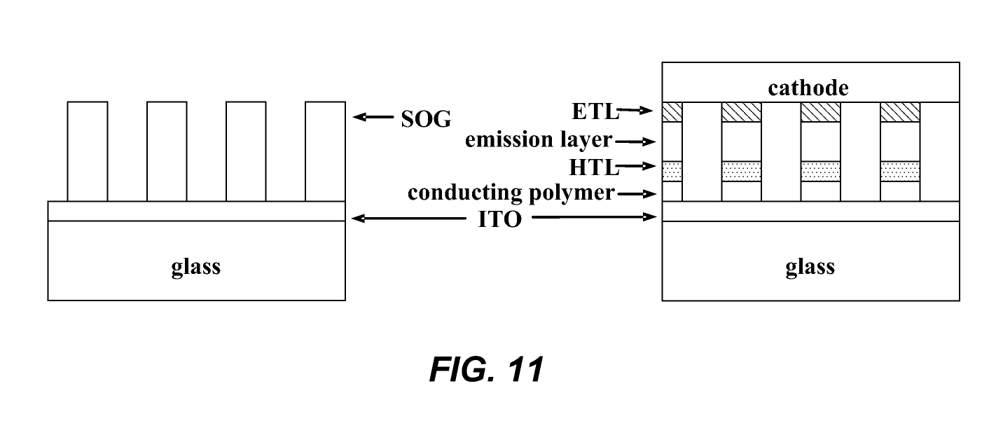

FIG. 11 provides a schematic illustration of a dielectric (e.g., silica) microstructure fabricated with a spin-on glass imprinting (SOGI) process on top of an ITO anode on a glass substrate (left), and the basic OLED device structure after deposition of multiple layers of organics to form a silica-organic intercalated OLED structure (right). This spin-on glass imprinting (SOGI) technology in accordance with the present invention is capable of creating a low refractive-index silica structure intercalated with the organic layers. An intercalated OLED structure is able to confine carrier flow, increase charge density, and, in addition, to significantly improve light extraction due to the low refractive index of silica compared to that of organics. Spin-on-glass (SOG) is a type of glass that can be applied as a liquid and cured (generally at about 400° C.) to form a layer of silica with a refractive index of approximately 1.38, significantly lower than organics (generally about 1.7) used for OLEDs. After spin-coating of SOG, an imprinting stamp can be used to define the microstructures of silica, in which the multiple layers of organics will be deposited. FIG. 11 illustrates schematically a silica microstructure fabricated with SOGI process on the top of ITO glass, and the basic OLED device structure after deposition of multiple layers of organics to form a silica-organic intercalated OLED structure (right).

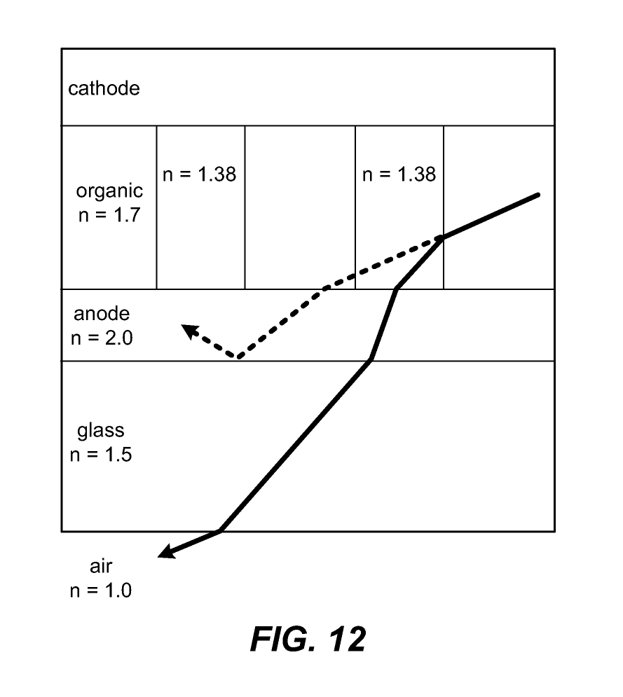

While the invention is in no way limited by this theory, it is believed that the mechanism of improved light extraction with intercalated silica-organic emission layer can be understood from FIG. 12. Without incorporation of a low refractive-index silica microstructure, the light will follow the dashed-line path that leads to total internal reflection (light propagates from a high-index medium to a low-index medium). When the low refractive-index microstructure is incorporated at the light-emission layer, bending of the light path takes place when the light hits the silica microstructure from the side, which results in the extraction of the otherwise trapped light out of the OLED device from the ITO glass side.

Hybrid LEDs

An alternative LED design in accordance with the invention is a hybrid of the inorganic and organic approaches described above. Such hybrid LED devices use organic emissive materials to form part of a p-n junction that can be positioned either on the top of the entire nanostructured LED device, or implemented in-between the individual nano structures.

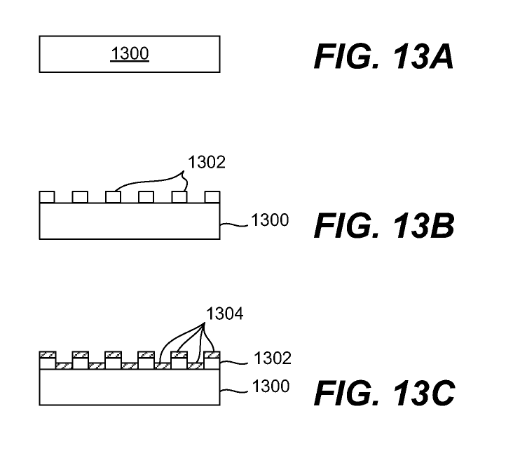

FIGS. 13A-C illustrate the fabrication of a hybrid organic/inorganic LED structure in accordance with the present invention. A bulk semiconductor (generally Si) substrate 1300 is provided (FIG. 13A). Single crystal n-GaN nanorods 1302 are grown on the bulk Si 1300 by nanoscale heteroepitaxy as described above, with or without patterning (FIG. 13B). Then, a p-type organic emissive material 1304, such as PEDOT, is deposited over the n-GaN nanorods to form the required p-n junction for the LED on top of and/or in between the individual nanostructures 1302 (FIG. 13C). The PEDOT deposited on the top of the n-GaN nanostructures (nanorods) can be optionally removed by chemical mechanical polishing (CMP) or ion beam etching, but this is not necessary. If the PEDOT deposited on the top of the n-GaN nanostructures is removed, the n-p junction is on the sidewall of the gap between the individual nanostructures 1302.

The doping types may be reversed so that an n-type organic emissive material is deposited on a p-type crystalline (inorganic) nanorod. A suitable n-type organic emissive material is Alq³.

Once the p-n junction is formed, a metal electrode layer is applied to the top of the LED structure and the electrodes are connected to a voltage source to complete the hybrid LED device.

### Alternative Embodiments

It should be understood that the doping types of the various structures described herein may be reversed in most or all cases, so that a structure described as p-doped in a disclosed embodiment may be n-doped and vice versa.

### CONCLUSION

The described LED/OLED embodiments of the invention incorporate emissive material nanostructures that confine current flow and provide internal light guiding which are believed to provide to improved device performance.

Although the foregoing invention has been described in some detail for purposes of clarity of understanding, certain changes and modifications will be apparent to those of skill in the art. It should be noted that there are many alternative ways of implementing both the process and compositions of the present invention. Accordingly, the present embodiments are to be considered as illustrative and not restrictive, and the invention is not to be limited to the details given herein. The following sample claims are representative of aspects of the present invention but should not be considered to be exhaustive.

1. A light emitting diode (LED) device structure, comprising:
a substrate;
an anode;
a cathode;
a micro or nano-structured light emissive material structure between the anode and cathode.

2. The LED device structure of claim 1, wherein the structured light emissive material structure comprises a p-n junction nanostructure comprising an interface with a doped single crystal direct band gap semiconductor.

3. The LED device structure of claim 2, wherein the p-n junction nanostructure comprises a single crystal direct band gap semiconductor nanorod having a p-doped portion and an n-doped portion.

4. The LED device structure of claim 2, wherein the p-n junction nanostructure comprises an n-doped single crystal direct band gap semiconductor nanorod on a p-doped indirect band gap semiconductor layer.

5. The LED device structure of claim 2, wherein the p-n junction nanostructure comprises p-doped single crystal direct band gap semiconductor nanorods and n-doped direct band gap semiconductor in the gaps between the p-doped nanorods.

6. The LED device structure of claim 5, wherein n-doped direct band gap semiconductor is also on top of the p-doped nanorods.

7. The LED device structure of claim 3, wherein the direct band gap semiconductor is selected from GaN and ZnO.

8. The LED device structure of claim 3, wherein the direct band gap semiconductor is GaN.

9. The LED device structure of claim 2, wherein the p-n junction nanostructure comprises a doped single crystal direct band gap semiconductor nanostructure and an organic light emissive material.

10. The LED device structure of claim 9, wherein the p-n junction nanostructure comprises doped single crystal direct band gap semiconductor nanorods and organic light emissive material in the gaps between the doped nanorods.

11. The LED device structure of claim 10, wherein the single crystal direct band gap semiconductor nanorods are n-doped and organic light emissive material in the gaps between nanorods is p-doped.

12. The LED device structure of claim 11, wherein the single crystal direct band gap semiconductor nanorods are n-doped GaN and the organic light emissive material in the gaps between nanorods is PEDOT.

13. The LED device structure of claim 11, wherein the single crystal direct band gap semiconductor nanorods are n-doped GaN and the organic light emissive material in the gaps between nanorods is Alq³.

14. The LED device structure of claim 1, wherein the structured light emissive material structure is organic.

15. The LED device structure of claim 14, wherein the structured organic light emissive material structure comprises nanorods of organic light emissive material separated by inactive material.

16. The LED device structure of claim 14, wherein the structured light emissive material is selected from the group consisting of Alq³ and PEDOT.

17. The LED device structure of claim 14, wherein the structured light emissive structure is imprinted.

18. The LED device structure of claim 14, wherein the structured light emissive material is intercalated with spin-on-glass imprinted dielectric.

19. The LED device structure of claim 14, further comprising a porous metal oxide disposed between the anode and the light emissive material structure.

20. A method of making a LED device structure according to claim 1.

21. A method of making a LED device structure according to claim 14, comprising non-vacuum fabrication processes.
